(19) United States
(12) Patent Application Publication
(10) Pub. No.: US 2024/0343039 A1
(43) Pub. Date: Oct. 17, 2024

(54) INKJET PRINTING APPARATUS AND INKJET PRINTING METHOD USING THE SAME

(71) Applicant: Samsung Display Co., LTD., Yongin-si (KR)

(72) Inventor: EUNSEOK KIM, Yongin-si (KR)

(21) Appl. No.: 18/420,055

(22) Filed: Jan. 23, 2024

(30) Foreign Application Priority Data
Apr. 14, 2023 (KR) 10-2023-0049550

(51) Int. Cl. B41J 2/14; H10K 71/13

(52) U.S. Cl. CPC B41J 2/1408; H10K 71/135

(57) ABSTRACT

An inkjet printing apparatus includes: a head module including a plurality of head nozzles and at least one cooling member, where the plurality of head nozzles are arranged in a row along a first direction and configured to discharge a liquid body on a substrate which moves along a second direction crossing the first direction, and the cooling member is spaced apart from the plurality of head nozzles in the second direction and configured to compensate for a temperature of the substrate; and a control module which provides a control signal for controlling the cooling member to the head module.

This application claims priority to Korean Patent Application No. 10-2023-0049550, filed on Apr. 14, 2023, and all the benefits accruing therefrom under 35 U.S.C. § 119, the content of which in its entirety is herein incorporated by reference.

### BACKGROUND

### 1. Field

The present disclosure relates generally to an inkjet printing apparatus. More particularly, the present disclosure relates to an inkjet printing apparatus and an inkjet printing method using the inkjet printing apparatus.

### 2. Description of the Related Art

In general, in manufacturing a display device, inkjet printing method may be used to form pixels on a substrate. That is, the pixels may be formed by printing the pixels on a surface of the substrate by discharging liquid on the substrate.

However, a position where the liquid is actually discharged to the substrate may deviate from a target position due to various reasons (e.g., thermal expansion of the substrate). In this case, an error may occur between the discharged position of the liquid and the target position. In order to reduce the error, many studies are being conducted.

### SUMMARY

Embodiments provide an inkjet printing apparatus that compensates for a temperature of a substrate.

Embodiments provide an inkjet printing method for compensating a temperature of a substrate.

An inkjet printing apparatus according to an embodiment of the present disclosure includes: a head module including a plurality of head nozzles and at least one cooling member, where the plurality of head nozzles are arranged in a row along a first direction and configured to discharge a liquid body on a substrate which moves along a second direction crossing the first direction, and the cooling member is spaced apart from the plurality of head nozzles in the second direction and configured to compensate for a temperature of the substrate; and a control module which provides a control signal for controlling the cooling member to the head module.

In an embodiment, the control signal may be a signal for controlling a temperature of the cooling member in response to an amount of thermal expansion of the substrate.

In an embodiment, the control signal may be a signal for controlling a separation distance between the cooling member and the substrate in response to an amount of thermal expansion of the substrate.

In an embodiment, the inkjet printing apparatus may further include a first fiducial mark disposed on the substrate and for measuring an amount of thermal expansion of the substrate.

In an embodiment, the first fiducial mark may be positioned at an edge of the substrate.

In an embodiment, the inkjet printing apparatus may further include a camera module which measures a position of the first fiducial mark. The control module may provide the control signal based on the measured position of the first fiducial mark.

In an embodiment, the inkjet printing apparatus may further include a stage on which the substrate is loaded and a second fiducial mark disposed on the stand and for measuring an amount of deformation of the camera module.

In an embodiment, the camera module may measure the position of the first fiducial mark and a position of the second fiducial mark, and the control module may provide the control signal based on the measured position of the first fiducial mark and the measured position of the second fiducial mark.

In an embodiment, a surface area of the cooling member may be equal to a sum of surface areas of the plurality of head nozzles.

In an embodiment, the cooling member may include a cooling water supply pipe through which a cooling water flows.

In an embodiment, the head module may move along the first direction.

An inkjet printing method according to an embodiment of the present disclosure includes: discharging a liquid body on a substrate; measuring an amount of thermal expansion of the substrate; and compensating a temperature of the substrate in response to a measured amount of thermal expansion of the substrate.

In an embodiment, a heat of the substrate may be transferred to a cooling member having a temperature relatively lower than a temperature of the substrate while compensating the temperature of the substrate.

In an embodiment, the inkjet printing method may further include controlling a temperature of the cooling member after measuring the amount of thermal expansion of the substrate.

In an embodiment, the inkjet printing method may further include controlling a separation distance between the cooling member and the substrate after measuring the amount of thermal expansion of the substrate.

In an embodiment, the cooling member may include a cooling water supply pipe through which a cooling water flows.

In an embodiment, the amount of thermal expansion of the substrate may be measured by measuring a position of a fiducial mark disposed on the substrate while measuring the amount of thermal expansion of the substrate.

In an embodiment, the fiducial mark may be positioned at an edge of the substrate.

In an embodiment, the position of the fiducial mark may be measured by a camera module.

In an embodiment, the amount of thermal expansion of the substrate may be measured by further measuring a position of another fiducial mark disposed on a stage under the substrate and calculating the amount of thermal expansion of the substrate based on both the measured position of a fiducial mark disposed on the substrate and the measured position of the another fiducial mark disposed on the stage.

An inkjet printing apparatus according to an embodiment of the present disclosure may include a head module including head nozzles and a cooling member spaced apart from the head nozzles, and a control module which provides a control signal for controlling the cooling member.

During an inkjet printing process, heat transferred from the head nozzles to a substrate may be transferred to the cooling member. Accordingly, a temperature of the substrate may be effectively compensated.

The control module may measure an amount of thermal expansion of the substrate during the inkjet printing process. The control module may provide the control signal for controlling the cooling member in response to the amount of thermal expansion of the substrate to the head module.

The head module may control a temperature of the cooling member and/or a separation distance between the cooling member and the substrate in response to the control signal. Accordingly, the cooling member may compensate the temperature of the substrate in response to the amount of thermal expansion of the substrate.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating an inkjet printing apparatus according to an embodiment of the present disclosure.

FIG. 2 is a plan view illustrating an embodiment of a head module included in the inkjet printing apparatus of FIG. 1.

FIG. 3 is a plan view illustrating another embodiment of a head module included in the inkjet printing apparatus of FIG. 1.

FIGS. 4A and 4B are plan views illustrating movement of a stage included in the inkjet printing apparatus of FIG. 1.

FIGS. 5A and 5B are side views illustrating movement of a stage included in the inkjet printing apparatus of FIG. 1.

FIG. 6 is a side view illustrating the inkjet printing apparatus of FIG. 1.

FIGS. 7A, 7B, and 8 are side views illustrating an inkjet printing apparatus according to another embodiment of the present disclosure.

FIG. 9 is a flowchart illustrating an inkjet printing method according to an embodiment of the present disclosure.

FIGS. 10, 11, 12, 13, 14, 15, 16, and 17 are diagrams illustrating the inkjet printing method of FIG. 9.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, embodiments of the present disclosure will be described in detail with reference to the accompanying drawings. The same reference numerals are used for the same components in the drawings, and redundant descriptions of the same components will be omitted.

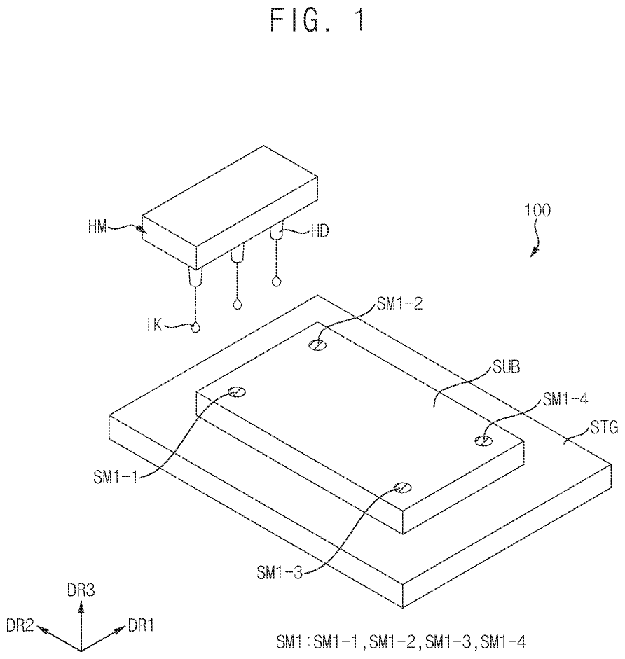

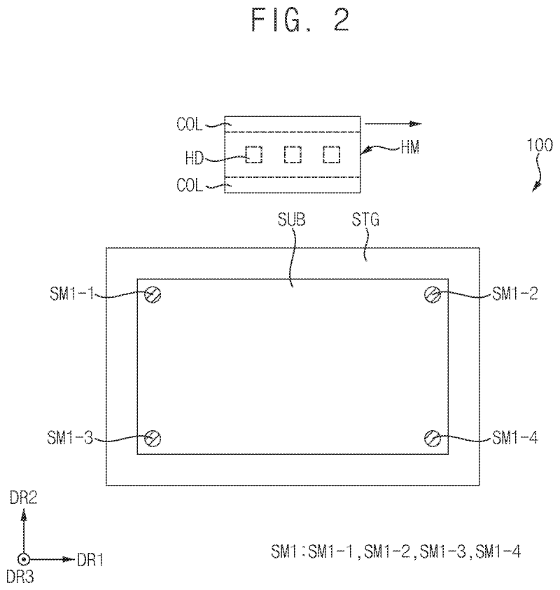

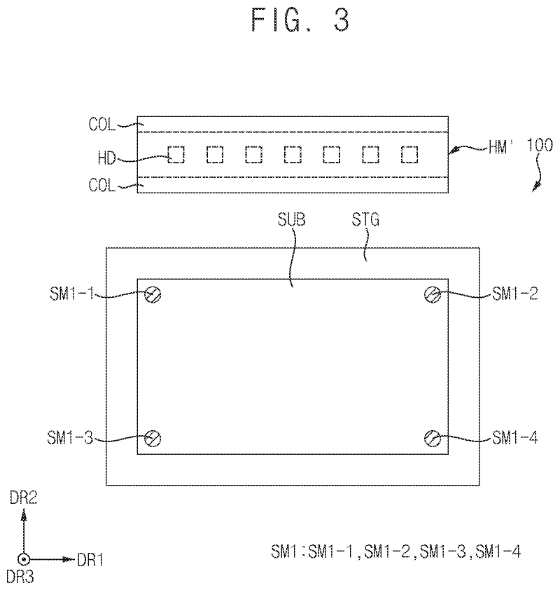

FIG. 1 is a perspective view illustrating an inkjet printing apparatus according to an embodiment of the present disclosure. FIG. 2 is a plan view illustrating an embodiment of a head module included in the inkjet printing apparatus of FIG. 1. FIG. 3 is a plan view illustrating another embodiment of a head module included in the inkjet printing apparatus of FIG. 1. As used herein, the “plan view” is a view in a third direction DR3 (i.e., thickness direction from a stage STG)

In this specification, a plane may be defined by a first direction DR1 and a second direction DR2 crossing the first direction DR1. For example, the first direction DR1 and the second direction DR2 may be perpendicular to each other. A direction normal to the plane may be a third direction DR3. In other words, the third direction DR3 may be perpendicular to each of the first direction DR1 and the second direction DR2.

Referring to FIGS. 1, 2, and 3, an inkjet printing apparatus 100 according to an embodiment of the present disclosure may include a stage STG, a first fiducial mark SM1 and a head module HM.

The stage STG may include an upper surface that is flat. A substrate SUB may be loaded on the stage STG. The stage STG may transfer the substrate SUB toward the head module HM in the second direction DR2. In an embodiment, the stage STG may include an electrostatic chuck for fixing and adsorbing the substrate SUB by electrostatic force. In this case, as the stage STG moves in the second direction DR2, the substrate SUB may be transferred toward the head module HM in the second direction DR2. Accordingly, the substrate SUB moves under the head module HM, and a liquid body IK may be discharged on the substrate SUB by the head module HM. Alternatively, the substrate SUB may be transferred toward the head module HM in the second direction DR2 while the stage STG is fixed using an air floating method.

The substrate SUB may be disposed on the stage STG. Specifically, a first surface of the substrate SUB may contact the stage STG. The substrate SUB may include a transparent material or an opaque material. The substrate SUB may be formed of a transparent resin substrate. A polyimide substrate may be an example of the transparent resin substrate. In this case, the polyimide substrate may include a first organic layer, a first barrier layer, a second organic layer, etc. Alternatively, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

In an embodiment, the first fiducial mark SM1 for measuring an amount of thermal expansion of the substrate SUB may be disposed on the substrate SUB. For example, the first fiducial mark SM1 may be disposed on a second surface, that is opposite to the first surface, of the substrate SUB. The liquid body IK may not be discharged to an area of the substrate SUB where the first fiducial mark SM1 is disposed.

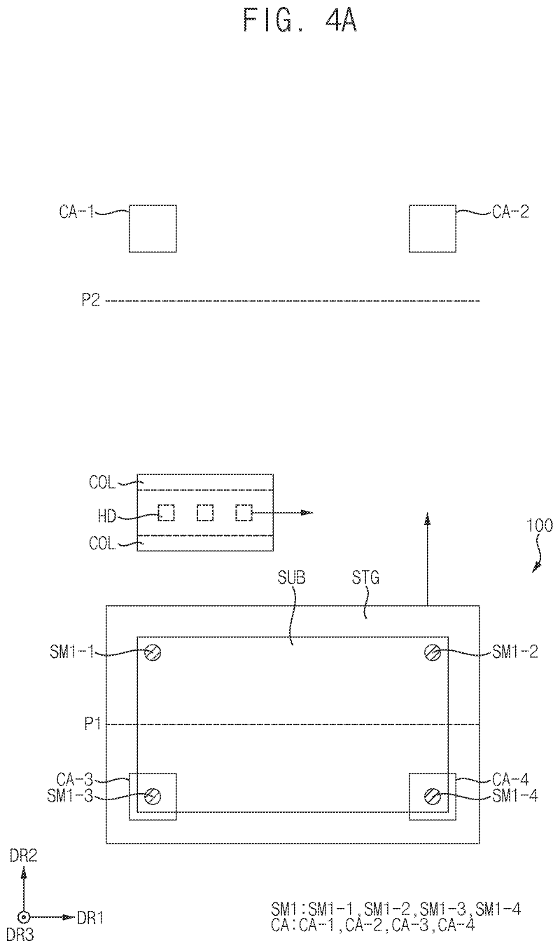

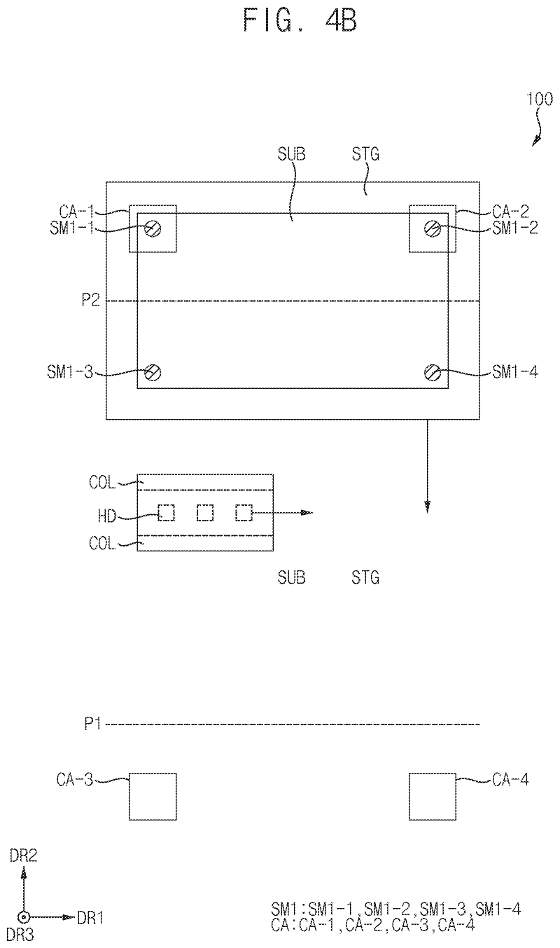

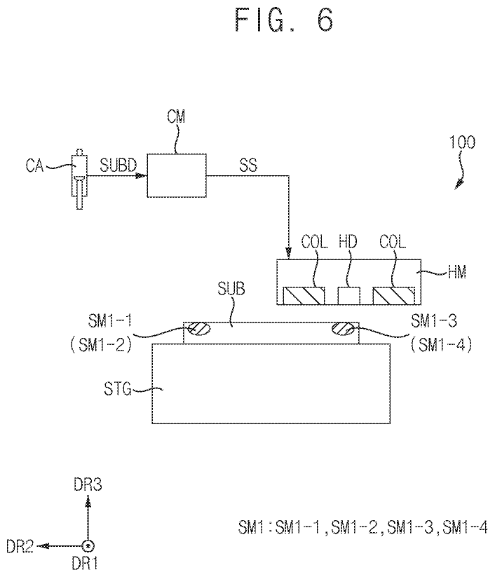

A position of the first fiducial mark SM1 may be measured by a camera module (e.g., a camera module CA of FIG. 4A). Based on the measured position of the first fiducial mark SM1, the amount of thermal expansion of the substrate SUB may be measured. In response to the amount of thermal expansion of the substrate SUB, a control module (e.g., a control module CM of FIG. 6) may provide a control signal (e.g., a control signal SS of FIG. 6) to the head module HM. The control signal may control a cooling member COL. A detailed description thereof will be described later with reference to FIGS. 4A, 4B, 5A, 5B, and 6.

In an embodiment, the first fiducial mark SM1 may include a (1-1)-th fiducial mark SM1-1, a (1-2)-th fiducial mark SM1-2, a (1-3)-th fiducial mark SM1-3, and a (1-4)-th fiducial mark SM1-4. The first fiducial mark SM1 may be positioned at an edge of the substrate SUB. In an embodiment, for example, the (1-1)-th fiducial mark SM1-1 may be positioned at a left upper edge of the second surface of the substrate SUB, and the (1-2)-th fiducial mark SM1-2 may be positioned at a right upper edge of the second surface of the substrate SUB. The (1-3)-th fiducial mark SM1-3 may be positioned at a left lower edge of the second surface of the substrate SUB, and the (1-4)-th fiducial mark SM1-4 may be positioned at a right lower edge of the second surface of the substrate SUB. However, the present disclosure is not limited thereto, and various numbers of the first fiducial mark SM1 may be provided.

The head module HM may include head nozzles HD and at least one cooling member COL. The head nozzles HD may be arranged in a row along the first direction DR1. Each of the head nozzles HD may discharge the liquid body IK on the substrate SUB in the form of droplets. Head nozzles HD may be provided in various numbers. For example, the head module HM may include 100 or more head nozzles HD.

In an embodiment, as illustrated in FIG. 2, a length in the first direction DR1 of an area where the head nozzles HD are disposed may be less than a length in the first direction DR1 of an area where the liquid body IK is discharged on the substrate SUB. In this case, the head module HM may be transferred in the first direction DR1 by a transfer unit. That is, in order to discharge the liquid body IK on the substrate SUB as a whole, the head module HM may be transferred in the first direction DR1 by the transfer unit during an inkjet printing process.

In another embodiment, as illustrated in FIG. 3, a length in the first direction DR1 of the area where the head nozzles HD are disposed may be greater than or equal to a length in the first direction DR1 of the area where the liquid body IK is discharged on the substrate. In this case, even if the head module HM is not transferred in the first direction DR1, the head module HM may discharge the liquid body IK on the substrate SUB as a whole. In other words, the head module HM may be fixed during the inkjet printing process.

The liquid body IK may be liquid including various materials. In an embodiment, for example, the liquid body IK may be an organic light emitting ink for forming a pixel included in a display device. In this case, the organic light emitting ink may be an ink in which an organic light emitting material and a solvent are mixed. The organic light emitting material may be a red organic light emitting material, a green organic light emitting material, or a blue organic light emitting material, and may emit light (e.g., red light, green light, or blue light) upon application of a voltage. The solvent may be a material capable of dissolving the organic light emitting material and may be a material that may be easily mixed with the organic light emitting material.

The liquid body IK may include a material with high viscosity. In this case, each of the head nozzles HD may be heated by a heating unit to have a temperature higher than room temperature. In an embodiment, for example, a temperature of each of the head nozzles HD may be about 50° C. . . . Accordingly, the fluidity of the liquid body IK is relatively increased, so that each of the head nozzles HD may effectively discharge the liquid body IK onto the substrate SUB.

The cooling member COL may be spaced apart from the head nozzles HD in the second direction DR2. In other words, the cooling member COL may be positioned to be spaced apart from the head nozzles HD in a direction parallel to a moving direction of the substrate SUB.

In an embodiment, for example, the head module HM may include two cooling members COL, and the cooling members COL may be spaced apart from each other in the second direction DR2 with the head nozzles HD interposed therebetween.

The cooling member COL may compensate for a temperature of the substrate SUB. To this end, the cooling member COL may have a temperature lower than room temperature. In an embodiment, the cooling member COL may include a cooling water supply pipe through which a cooling water flows. Accordingly, even though heat is transferred from the substrate SUB to the cooling member COL, the cooling member COL may maintain a constant temperature using the cooling water. In an embodiment, for example, a temperature of the cooling member COL may be about −5° C. . . . However, the present disclosure is not limited thereto, and the cooling member COL may be provided at various temperatures in consideration of the sum of the surface areas and the temperature of each of the head nozzles HD

In addition, the cooling member COL may be provided with various surface areas in consideration of the sum of the surface areas and the temperature of each of the head nozzles HD. In an embodiment, the surface area of the cooling member COL may be equal to the sum of the surface areas of the head nozzles HD. However, the present disclosure is not limited thereto, and the surface area of the cooling member COL may be different from the sum of the surface areas of the head nozzles HD in another embodiment.

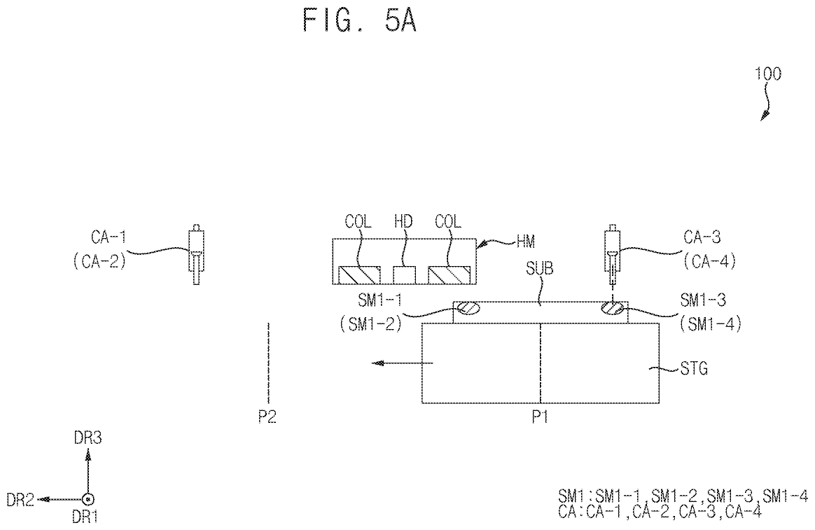

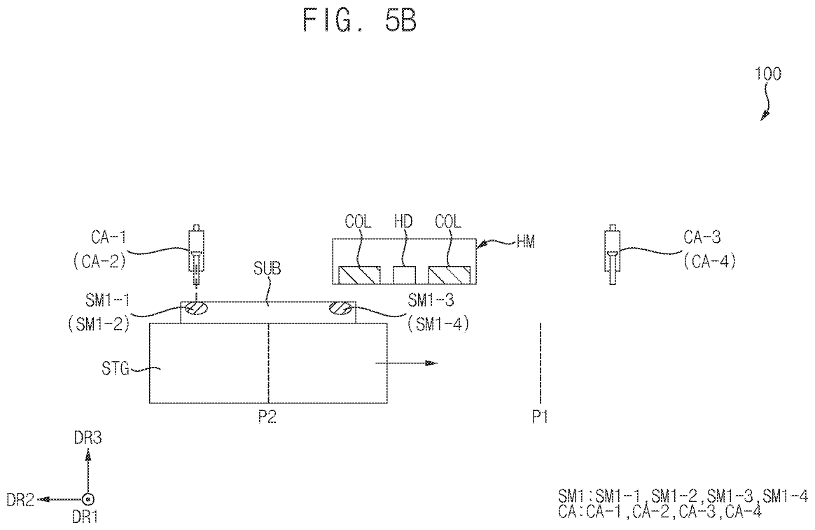

FIGS. 4A and 4B are plan views illustrating movement of a stage included in the inkjet printing apparatus of FIG. 1. FIGS. 5A and 5B are side views illustrating movement of a stage included in the inkjet printing apparatus of FIG. 1. FIG. 6 is a side view illustrating the inkjet printing apparatus of FIG. 1.

Referring to FIGS. 4A, 4B, 5A, 5B, and 6, the inkjet printing apparatus 100 according to an embodiment of the present disclosure may include the stage STG, the first fiducial mark SM1, the head module HM, a camera module CA, and a control module CM. The head module HM may include the head nozzles HD and the cooling member COL.

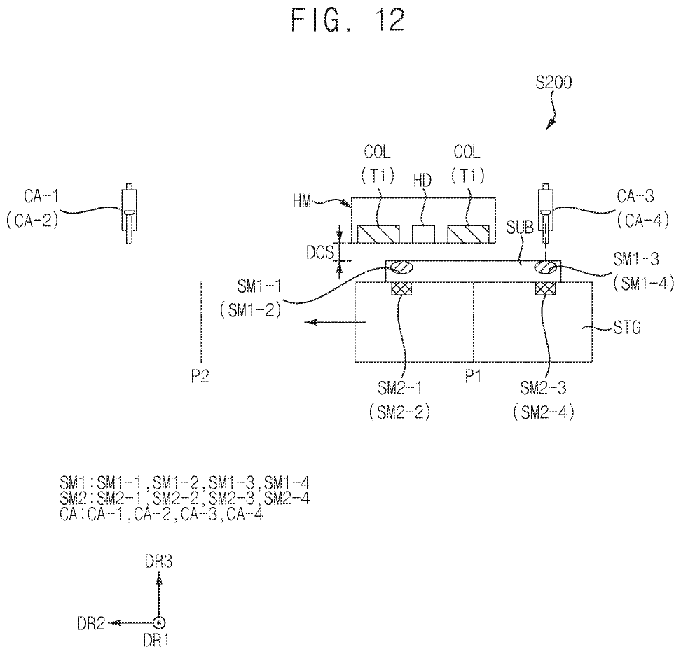

The substrate SUB may be loaded on the stage STG. The stage STG may transfer the substrate SUB toward the head module HM in the second direction DR2. In an embodiment, as the stage STG moves in the second direction DR2, the substrate SUB may be transferred toward the head module HM in the second direction DR2. Accordingly, the substrate SUB moves under the head module HM, and the liquid body IK may be discharged on the substrate SUB by the head module HM. In this case, a separation distance (See DCS in FIG. 12) between each of the head nozzles HD included in the head module HM and the substrate SUB in the third direction DR3 may be about 1 millimeter or less.

After moving in the second direction DR2, the stage STG may return to its initial position by moving in a direction opposite to the second direction DR2. Specifically, an initial position of a center of the stage STG may be defined as a first point P1. In addition, when the stage STG moves in the second direction DR2, a new position of the center of the stage STG may be defined as a second point P2. In this case, the center of the stage STG may move from the first point P1 to the second point P2 in the second direction DR2 and then move from the second point P2 to the first point P1 in the direction opposite to the second direction DR2. In other words, the stage STG may reciprocate.

The first fiducial mark SM1 for measuring the amount of thermal expansion of the substrate SUB may be disposed on the substrate SUB. In an embodiment, for example, the first fiducial mark SM1 may include the (1-1)-th fiducial mark SM1-1, the (1-2)-th fiducial mark SM1-2, the (1-3)-th fiducial mark SM1-3, and the (1-4)-th fiducial mark SM1-4.

The stage STG may move such that the camera module CA may be disposed on the substrate SUB. The camera module CA may measure the position of the first fiducial mark SM1. In an embodiment, the camera module CA may include a first camera module CA-1 for measuring the (1-1)-th fiducial mark SM1-1, a second camera module CA-2 for measuring the (1-2)-th fiducial mark SM1-2, a third camera module CA-3 for measuring the (1-3)-th fiducial mark SM1-3, and a fourth camera module CA-4 for measuring the (1-4)-th fiducial mark SM1-4. That is, the camera module CA may be provided in a number equal to the number of the first fiducial mark SM1.

Specifically, the first camera module CA-1 may overlap the (1-1)-th fiducial mark SM1-1 in a plan view when the center of the stage STG is positioned at the second point P2. That is, the first camera module CA-1 may measure the position of the (1-1)-th fiducial mark SM1-1 when the center of the stage STG is positioned at the second point P2.

The second camera module CA-2 may overlap the (1-2)-th fiducial mark SM1-2 in a plan view when the center of the stage STG is positioned at the second point P2. That is, the second camera module CA-2 may measure the position of the (1-2)-th fiducial mark SM1-2 when the center of the stage STG is positioned at the second point P2.

The third camera module CA-3 may overlap the (1-3)-th fiducial mark SM1-3 in a plan view when the center of the stage STG is positioned at the first point P1. That is, the third camera module CA-3 may measure the position of the (1-3)-th fiducial mark SM1-3 when the center of the stage STG is positioned at the first point P1.

The fourth camera module CA-4 may overlap the (1-4)-th fiducial mark SM1-4 in a plan view when the center of the stage STG is positioned at the first point P1. That is, the fourth camera module CA-4 may measure the position of the (1-4)-th fiducial mark SM1-4 when the center of the stage STG is positioned at the first point P1.

As illustrated in FIG. 6, a position data SUBD of the first fiducial mark SM1 measured by the camera module CA may be provided to the control module CM. The control module CM may generate a control signal SS for controlling the cooling member COL based on the position data SUBD of the first fiducial mark SM1.

Specifically, the control module CM may measure the amount of thermal expansion of the substrate SUB based on the position data SUBD of the first fiducial mark SM1. The control module CM may generate the control signal SS for controlling the cooling member COL in response to the amount of thermal expansion of the substrate SUB. The control module CM may provide the control signal SS to the head module HM. The head module HM may control the cooling member COL in response to the control signal SS.

In an embodiment, the control signal SS may be a signal for controlling a temperature of the cooling member COL in response to the amount of thermal expansion of the substrate SUB. That is, the temperature of the cooling member COL may increase or decrease by the control signal SS.

In another embodiment, the control signal SS may be a signal for controlling a separation distance between the cooling member COL and the substrate SUB in the third direction DR3 in response to the amount of thermal expansion of the substrate SUB. That is, the separation distance between the cooling member COL and the substrate SUB may increase or decrease by the control signal SS.

In still another embodiment, the control signal SS may be a signal for controlling each of the temperature of the cooling member COL and the separation distance between the cooling member COL and the substrate SUB in response to the amount of thermal expansion of the substrate SUB. In this case, the temperature of the cooling member COL and the separation distance between the cooling member COL and the substrate SUB may be simultaneously controlled by the control signal SS.

When the liquid body IK includes a high-viscosity material, each of the head nozzles HD may be heated to a temperature higher than room temperature. In addition, a separation distance between each of the head nozzles HD and the substrate SUB in the third direction DR3 may be about 1 millimeter or less. In this case, heat may be transferred from the head nozzles HD having a relatively high temperature to the substrate SUB having a relatively low temperature by radiation and convection. Accordingly, the substrate SUB receiving the heat may thermally expand. When the substrate SUB thermally expands during the inkjet printing process, a problem in that the liquid body IK is not discharged to a target position of the substrate SUB may occur.

In order to prevent the liquid body IK from being not discharged to the target position of the substrate SUB, the inkjet printing apparatus 100 according to an embodiment of the present disclosure may include the head module HM including the head nozzles HD and the cooling member COL spaced apart from the head nozzles HD in the second direction DR2, the camera module CA measuring the first fiducial mark SM1, and the control module CM providing the control signal SS to control the cooling member COL.

The cooling member COL may be positioned to be spaced apart from the head nozzles HD in the direction (i.e., the second direction DR2) parallel to the moving direction of the substrate SUB. In an embodiment, for example, while the substrate SUB is transferred toward the head module HM in the second direction DR2, the substrate SUB may overlap in an order of the cooling member COL, the head nozzles HD, and the cooling member COL in a plan view. In this case, heat transferred from the head nozzles HD to the substrate SUB may be transferred to the cooling member COL having a relatively lower temperature than the temperature of the substrate SUB by radiation and convection. Accordingly, the temperature of the substrate SUB may be effectively compensated (i.e., limiting the increase of the temperature of the substrate SUB).

During the inkjet printing process, the camera module CA may measure the position of the first fiducial mark SM1 disposed on the substrate SUB. In an embodiment, for example, the camera module CA may measure the positions of the first fiducial mark SM1 both when the center of the stage STG is positioned at the first point P1 and at the second point P2. However, the present disclosure is not limited thereto, and in another embodiment, the camera module CA may measure the position of the first fiducial mark SM1 only when the center of the stage STG is positioned at the first point P1. Alternatively, the camera module CA may measure the position of the first fiducial mark SM1 only when the center of the stage STG is positioned at the second point P2. The camera module CA may provide the position data SUBD of the first fiducial mark SM1 to the control module CM.

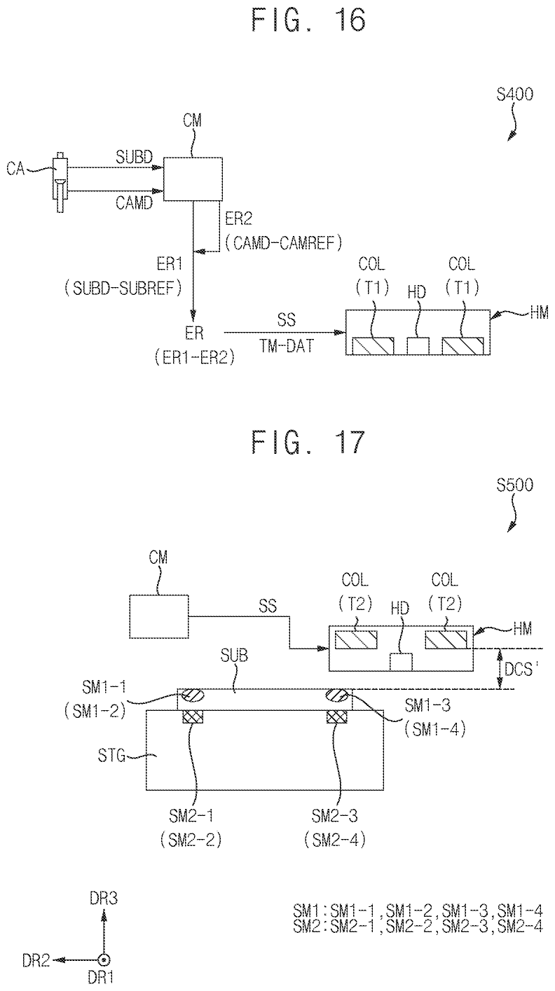

The control module CM may provide the control signal SS for controlling the cooling member COL to the head module HM based on the position data SUBD of the first fiducial mark SM1. Specifically, the control module CM may calculate an error value by comparing the position data SUBD of the first fiducial mark SM1 with a substrate reference value (e.g., a substrate reference value SUBREF of FIG. 16). The substrate reference value may refer to a position value of the first fiducial mark SM1 before the inkjet printing process starts.

Accordingly, the error value may refer to an error value generated as the substrate SUB thermally expands during the inkjet printing process. The control module CM may generate the control signal SS for correcting the error value based on a stored thermal expansion data (e.g., a thermal expansion data TM-DAT of FIG. 16).

As described above, the head module HM may control the temperature of the cooling member COL and/or the separation distance between the cooling member COL and the substrate SUB in the third direction DR3 in response to the control signal SS. In an embodiment, for example, when the temperature of the cooling member COL is increased, the amount of heat transferred from the substrate SUB to the cooling member COL may be reduced. For another example, when the temperature of the cooling member COL is decreased, the amount of heat transferred from the substrate SUB to the cooling member COL may be increased. For still another example, when the separation distance between the cooling member COL and the substrate SUB in the third direction DR3 is increased, the amount of heat transferred from the substrate SUB to the cooling member COL may be reduced. For still another example, when the separation distance between the cooling member COL and the substrate SUB in the third direction DR3 is decreased, the amount of heat transferred from the substrate SUB to the cooling member COL may be increased.

As such, by controlling the temperature of the cooling member COL and/or the separation distance between the cooling member COL and the substrate SUB in the third direction DR3, an amount of heat transferred from the head nozzles HD to the substrate SUB may be equal to an amount of heat transferred from the substrate SUB to the cooling member COL. Accordingly, thermal expansion of the substrate SUB may be prevented by maintaining the temperature of the substrate SUB constant. Therefore, the problem that the liquid body is not discharged to the target position of the substrate SUB, which occurs when the substrate SUB thermally expands during the inkjet printing process, may be suppressed.

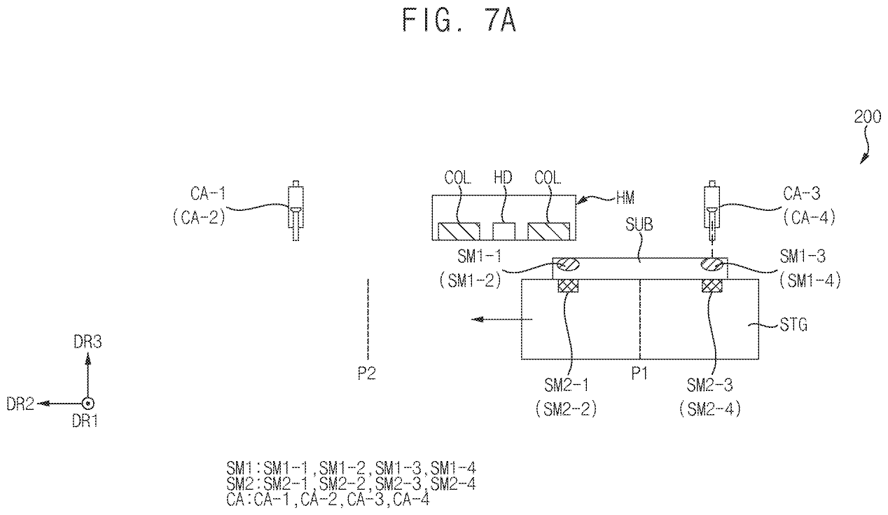

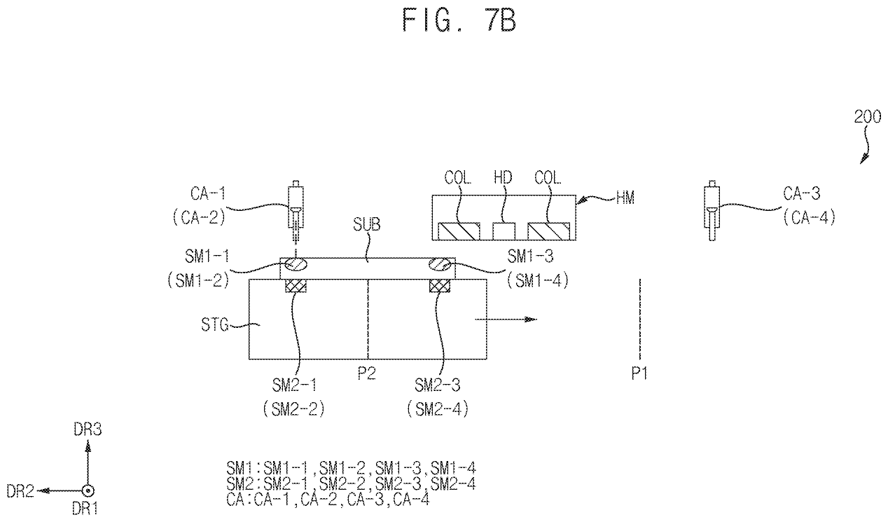

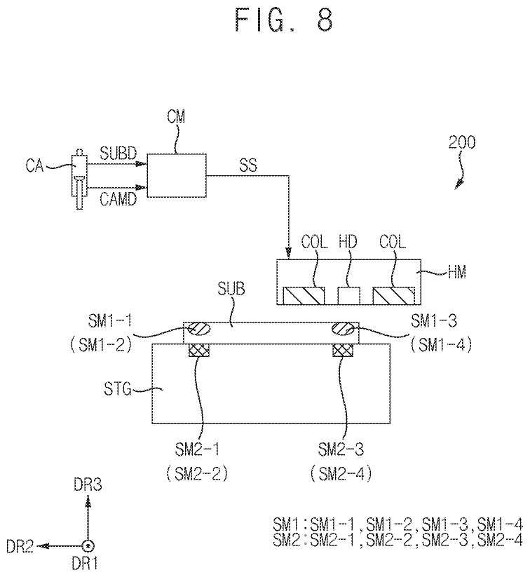

FIGS. 7A, 7B, and 8 are side views illustrating an inkjet printing apparatus according to another embodiment of the present disclosure.

Referring to FIGS. 7A, 7B, and 8, an inkjet printing apparatus 200 according to another embodiment of the present disclosure may include a stage STG, a first fiducial mark SM1, a second fiducial mark SM2, a head module HM, a camera module CA, and a control module CM. The head module HM may include head nozzles HD and a cooling member COL.

The inkjet printing apparatus 200 may be substantially the same as the inkjet printing apparatus 100 described with reference to FIGS. 4A, 4B, 5A, 5B, and 6, except that the second fiducial mark SM2 is disposed on the stage STG. Hereinafter, descriptions overlapping descriptions of the inkjet printing apparatus 100 described with reference to FIGS. 4A, 4B, 5A, 5B, and 6 will be omitted or simplified.

The substrate SUB may be disposed on the stage STG. Specifically, a first surface of the substrate SUB (e.g., bottom surface) may contact a first surface of the stage STG (e.g., top surface).

The first fiducial mark SM1 for measuring the amount of thermal expansion of the substrate SUB may be disposed on the substrate SUB. For example, the first fiducial mark SM1 may be disposed on a second surface (e.g., top surface), that is opposite to the first surface, of the substrate SUB. In an embodiment, the first fiducial mark SM1 may include the (1-1)-th fiducial mark SM1-1, the (1-2)-th fiducial mark SM1-2, the (1-3)-th fiducial mark SM1-3, and the (1-4)-th fiducial mark SM1-4.

The second fiducial mark SM2 for measuring an amount of deformation of the camera module CA may be disposed on the stage STG. For example, the second fiducial mark SM2 may be disposed on the first surface of the stage STG. In an embodiment, the second fiducial mark SM2 may include a (2-1)-th fiducial mark SM2-1, a (2-2)-th fiducial mark SM2-2, a (2-3)-th fiducial mark SM2-3, and a (2-4)-th fiducial mark SM2-4.

The first fiducial mark SM1 may be positioned at the edge of the substrate SUB, and the second fiducial mark SM2 may be positioned at an edge of the stage STG. In addition, the first fiducial mark SM1 may overlap the second fiducial mark SM2 in a plan view. In an embodiment, for example, the (1-1)-th fiducial mark SM1-1 may be positioned at the left upper edge of the second surface of the substrate SUB, and the (2-1)-th fiducial mark SM2-1 may be positioned at a left upper edge of the first surface of the stage STG. The (1-2)-th fiducial mark SM1-2 may be positioned at the right upper edge of the second surface of the substrate SUB, and the (2-2)-th fiducial mark SM2-2 may be positioned at a right upper edge of the first surface of the stage STG. The (1-3)-th fiducial mark SM1-3 may be positioned at the left lower edge of the second surface of the substrate SUB, and the (2-3)-th fiducial mark SM2-3 may be positioned at a left lower edge of the first surface of the stage STG. The (1-4)-th fiducial mark SM1-4 may be positioned at the right lower edge of the second surface of the substrate SUB, and the (2-4)-th fiducial mark SM2-4 may be positioned at a right lower edge of the first surface of the stage STG.

The camera module CA may be disposed on the substrate SUB. The camera module CA may measure the positions of the first fiducial mark SM1 and the second fiducial mark SM2. In an embodiment, the camera modules CA may include a first camera module CA-1, a second camera module CA-2, a third camera module CA-3, and a fourth camera module CA-4. The first camera module CA-1 may measure the positions of the (1-1)-th fiducial mark SM1-1 and the (2-1)-th fiducial mark SM2-1. The second camera module CA-2 may measure the positions of the (1-2)-th fiducial mark SM1-2 and the (2-2)-th fiducial mark SM2-2. The third camera module CA-3 may measure the positions of the (1-3)-th fiducial mark SM1-3 and the (2-3)-th fiducial mark SM2-3. The fourth camera module CA-4 may measure the positions of the (1-4)-th fiducial mark SM1-4 and the (2-4)-th fiducial mark SM2-4. That is, the camera module CA, the first fiducial mark SM1, and the second fiducial mark SM2 may be provided in equal numbers.

Specifically, the first camera module CA-1 may overlap each of the (1-1)-th fiducial mark SM1-1 and the (2-1)-th fiducial mark SM2-1 in a plan view when the center of the stage STG is positioned at the second point P2. That is, the first camera module CA-1 may measure each of the positions of the (1-1)-th fiducial mark SM1-1 and the (2-1)-th fiducial mark SM2-1 when the center of the stage STG is positioned at the second point P2.

The second camera module CA-2 may overlap each of the (1-2)-th fiducial mark SM1-2 and the (2-2)-th fiducial mark SM2-2 in a plan view when the center of the stage STG is positioned at the second point P2. That is, the second camera module CA-2 may measure each of the positions of the (1-2)-th fiducial mark SM1-2 and the (2-2)-th fiducial mark SM2-2 when the center of the stage STG is positioned at the second point P2.

The third camera module CA-3 may overlap each of the (1-3)-th fiducial mark SM1-3 and the (2-3)-th fiducial mark SM2-3 in a plan view when the center of the stage STG is positioned at the first point P1. That is, the third camera module CA-3 may measure each of the positions of the (1-3)-th fiducial mark SM1-3 and the (2-3)-th fiducial mark SM2-3 when the center of the stage STG is positioned at the first point P1.

The fourth camera module CA-4 may overlap each of the (1-4)-th fiducial mark SM1-4 and the (2-4)-th fiducial mark SM2-4 in a plan view when the center of the stage STG is positioned at the first point P1. That is, the fourth camera module CA-4 may measure each of the positions of the (1-4)-th fiducial mark SM1-4 and the (2-4)-th fiducial mark SM2-4 when the center of the stage STG is positioned at the first point P1.

As illustrated in FIG. 8, the camera module CA may provide a measured position data SUBD of the first fiducial mark SM1 and a measured position data CAMD of the second fiducial mark SM2 to the control module CM. The control module CM may generate a control signal SS for controlling the cooling member COL based on the position data SUBD of the first fiducial mark SM1 and the position data CAMD of the second fiducial mark SM2.

Specifically, the control module CM may measure the amount of deformation of the camera module CA based on the position data CAMD of the second fiducial mark SM2. The amount of deformation of the camera module CA may refer to a position change amount of the camera module CA according to shaking of the camera module CA. In addition, the control module CM may measure the amount of thermal expansion of the substrate SUB based on the position data SUBD of the first fiducial mark SM1 and the position data CAMD of the second fiducial mark SM2. The control module CM may generate the control signal SS for controlling the cooling member COL in response to the amount of thermal expansion of the substrate SUB.

The control signal SS may be a signal for controlling the temperature of the cooling member COL and/or the separation distance between the cooling member COL and the substrate SUB in the third direction DR3. The control module CM may provide the control signal SS to the head module HM. The head module HM may control the cooling member COL in response to the control signal SS.

During the inkjet printing process, the camera module CA measuring the first fiducial mark SM1 for measuring the amount of thermal expansion of the substrate SUB may be shaken. That is, the position of the camera module CA may change during the inkjet printing process. The control module CM may calculate an error value by comparing the position data SUBD of the first fiducial mark SM1 with a substrate reference value (e.g., a substrate reference value SUBREF of FIG. 16). In this case, the error value may include an error value due to thermal expansion of the substrate SUB and an error value due to a change in position of the camera module CA.

In the inkjet printing apparatus 200 according to another embodiment of the present disclosure, the second fiducial mark SM2 may be disposed on the stage STG that is relatively not thermally expanded during the inkjet printing process. In other words, the second fiducial mark SM2 may be fixed on the stage STG during the inkjet printing process. That is, the position change amount of the camera module CA may be measured from the position data CAMD of the second fiducial mark SM2 measured by the camera module CA.

The control module CM may calculate an error value (e.g., an error value ER of FIG. 16) due to thermal expansion of the substrate SUB by subtracting an error value (e.g., a second error value ER2 of FIG. 16) due to a change in position of the camera module CA from the above error value. That is, the control module CM may more accurately measure the amount of thermal expansion of the substrate SUB based on the position data SUBD of the first fiducial mark SM1 and the position data CAMD of the second fiducial mark SM2. The control module CM may generate the control signal SS for controlling the cooling member COL in response to the amount of thermal expansion of the substrate SUB.

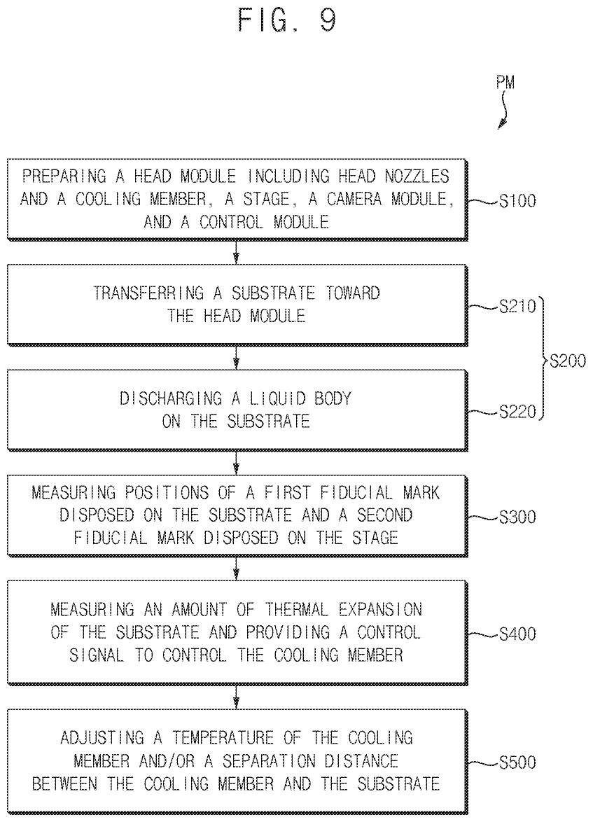

FIG. 9 is a flowchart illustrating an inkjet printing method according to an embodiment of the present disclosure.

Referring to FIG. 9, an inkjet printing method PM according to an embodiment of the present disclosure may include preparing a head module including head nozzles and a cooling member, a stage, a camera module, and a control module (S100), transferring a substrate toward the head module (S210), discharging a liquid body on the substrate by the head nozzles (S220), measuring a first fiducial mark disposed on the substrate and a second fiducial mark disposed on the stage by the camera module (S300), measuring an amount of thermal expansion of the substrate and providing a control signal to control the cooling member in response to the amount of thermal expansion of the substrate (S400), and adjusting a temperature of the cooling member and/or a separation distance between the cooling member and the substrate in the third direction DR3 according to the control signal (S500).

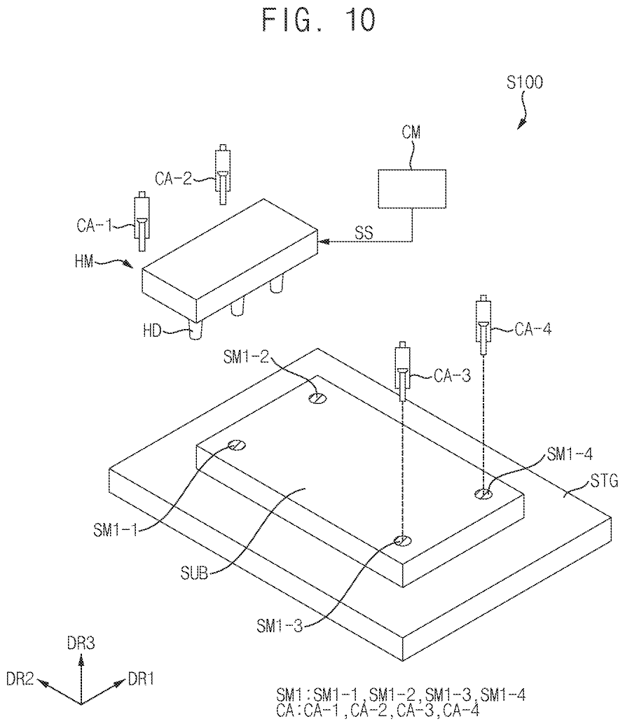

FIGS. 10, 11, 12, 13, 14, 15, 16, and 17 are diagrams illustrating the inkjet printing method of FIG. 9.

Referring to FIGS. 9 and 10, a head module HM including head nozzles HD and a cooling member, a stage STG, a camera module CA, and a control module CM may be prepared (S100).

A substrate SUB may be loaded on the stage STG. A first fiducial mark SM1 may be disposed on the substrate SUB. Before the inkjet printing process starts, the camera module CA may measure the position of the first fiducial mark SM1. In other words, before transferring heat from the head nozzles HD to the substrate SUB, the camera module CA may measure the position of the first fiducial mark SM1. Accordingly, based on the position of the first fiducial mark SM1 before the substrate SUB is thermally expanded, the control module CM may measure a substrate reference value (e.g., a substrate reference value SUBREF of FIG. 16).

A second fiducial mark may be disposed on the stage STG. Before the inkjet printing process starts, the camera module CA may measure the position of the second fiducial mark SM2. Accordingly, based on the position of the second fiducial mark before the camera module CA is deformed, the control module CM may measure a camera reference value (e.g., a camera reference value CAMREF of FIG. 16). The control module CM may provide a control signal SS to the head module HM in a later step.

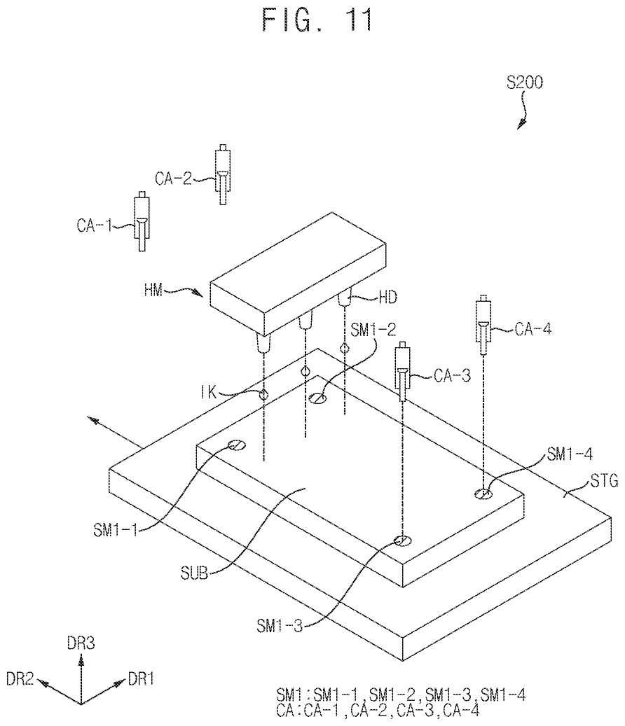

Referring to FIGS. 11 and 12, the substrate SUB may be transferred toward the head module HM, and a liquid body IK may be discharged on the substrate SUB by the head nozzles HD (S200).

As the stage STG moves in the second direction DR2, the substrate SUB may be transferred toward the head module HM in the second direction DR2. Accordingly, the substrate SUB may move under the head module HM, and the liquid body IK may be discharged on the substrate SUB by the head nozzles HD.

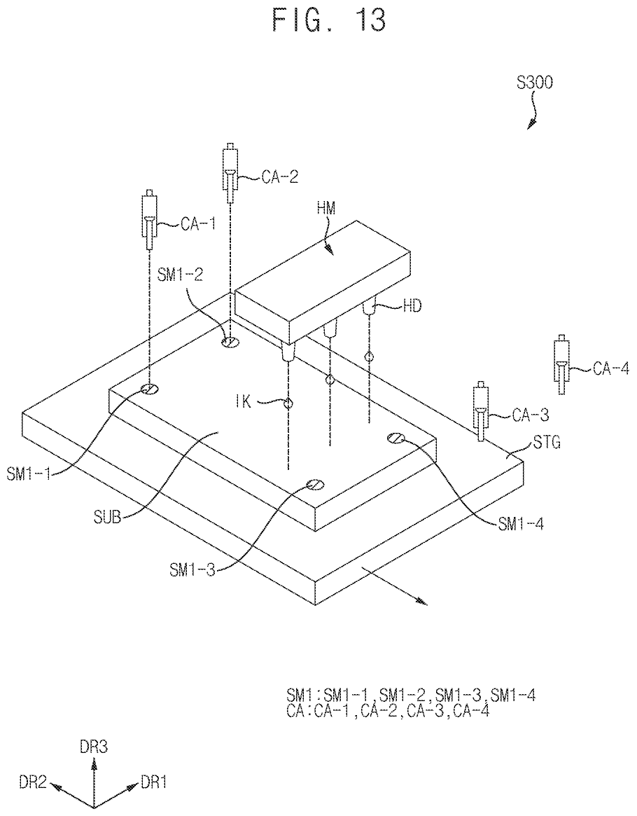

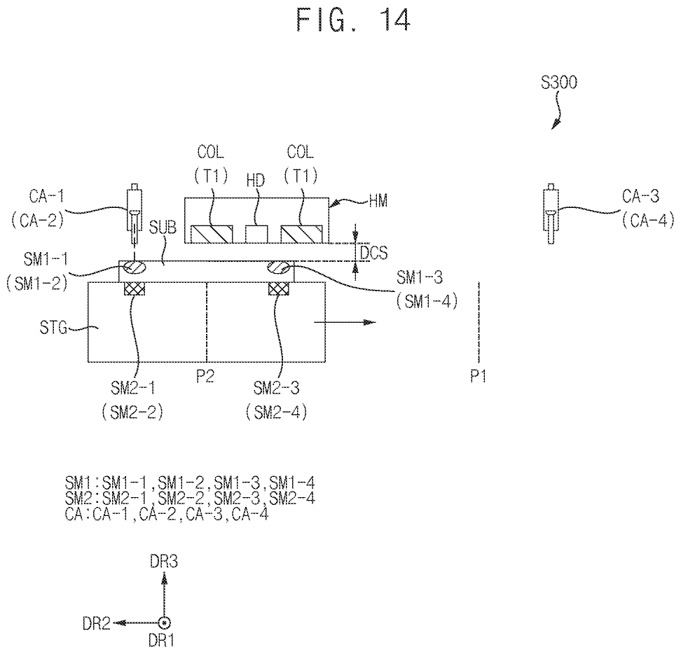

Each of the head nozzles HD may be heated by a heating unit to have a temperature higher than room temperature. In addition, the cooling member COL may have a temperature lower than room temperature. While the substrate SUB is transferred toward the head module HM in the second direction DR2, the substrate SUB may overlap in an order of the cooling member COL, the head nozzles HD, and the cooling member COL in a plan view. In this case, heat transferred from the head nozzles HD to the substrate SUB may be transferred to the cooling member COL by radiation and convection. Accordingly, the temperature of the substrate SUB may be compensated. In this case, a temperature of the cooling member COL may be defined as a first temperature T1, and a separation distance between the cooling member COL and the substrate SUB in the third direction DR3 may be defined as a first distance DCS. Referring to FIGS. 13 and 14, each of the first fiducial mark SM1 disposed on the substrate SUB and the second fiducial mark SM2 disposed on the stage STG may be measured by the camera module CA (S300).

During the inkjet printing process, the camera module CA may measure each of the positions of the first fiducial mark SM1 disposed on the substrate SUB and the second fiducial mark SM2 disposed on the stage STG. In an embodiment, for example, a first camera module CA-1 may measure each of the positions of a (1-1)-th fiducial mark SM1-1 and a (2-1)-th fiducial mark SM2-1 when the center of the stage STG is positioned at a second point P2. A second camera module CA-2 may measure each of the positions of a (1-2)-th fiducial mark SM1-2 and a (2-2)-th fiducial mark SM2-2 when the center of the stage STG is positioned at the second point P2.

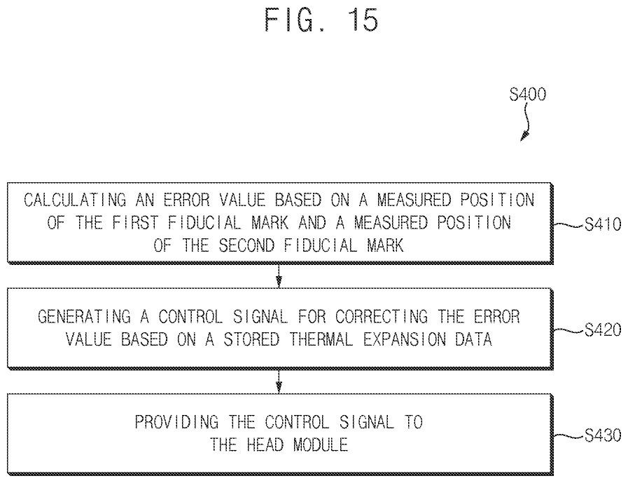

Referring to FIGS. 15 and 16, an amount of thermal expansion of the substrate SUB may be measured, and the control signal SS may be provided to control the cooling member COL in response to the amount of thermal expansion of the substrate SUB (S400). In this case, an error value ER may be calculated based on the measured position of the first fiducial mark SM1 and the measured position of the second fiducial mark SM2 (S410). Based on a stored thermal expansion data TM-DAT, the control signal SS for correcting the error value ER may be generated by the control module CM (S420), and the control signal SS may be provided to the head module HM (S430).

The camera module CA may provide each of the position data SUBD of the first fiducial mark SM1 and the position data CAMD of the second fiducial mark SM2 to the control module CM.

The control module CM may calculate the error value ER according to the thermal expansion of the substrate SUB based on the position data SUBD of the first fiducial mark SM1 and the position data CAMD of the second fiducial mark SM2.

Specifically, the control module CM may calculate a first error value ER1 by comparing a substrate reference value SUBREF with the position data SUBD of the first fiducial mark SM1 (i.e., by subtracting the substrate reference value SUBREF from the value of the position data SUBD of the first fiducial mark SM1). In this case, the first error value ER1 may include the error value ER due to thermal expansion of the substrate SUB and a second error value ER2 due to a change in position of the camera module CA.

The control module CM may measure a position change amount of the camera module CA based on the position data CAMD of the second fiducial mark SM2. In other words, the control module CM may calculate the second error value ER2 by comparing the position data CAMD of the second fiducial mark SM2 with a camera reference value CAMREF (i.e., by subtracting the camera reference value CAMREF from the value of the position data CAMD of the second fiducial mark SM2). In this case, the second error value ER2 may mean an error value according to a change in position of the camera module CA. The control module CM may calculate the error value ER according to the thermal expansion of the substrate SUB by subtracting the second error value ER2 from the first error value ER1.

Based on the stored thermal expansion data TM-DAT, the control module CM may generate the control signal SS for correcting the error value ER according to the thermal expansion of the substrate SUB. The control module CM may provide the control signal SS to the head module HM.

Referring to FIG. 17, a temperature of the cooling member COL and/or a separation distance between the cooling member COL and the substrate SUB in the third direction DR3 may be adjusted by the control signal SS (S500).

The head module HM may control the cooling member COL in response to the control signal SS.

The control signal SS may be a signal for controlling the temperature of the cooling member COL and/or the separation distance between the cooling member COL and the substrate SUB in the third direction DR3 in response to the amount of thermal expansion of the substrate SUB.

In an embodiment, for example, the temperature of the cooling member COL may be controlled by the control signal SS. In this case, a controlled temperature of the cooling member COL may be defined as a second temperature T2. The second temperature T2 may be different from the first temperature T1 of FIG. 14.

For another example, the separation distance between the cooling member COL and the substrate SUB in the third direction DR3 may be controlled by the control signal SS. In this case, a controlled distance between the cooling member COL and the substrate SUB may be defined as a second distance DCS′. The second distance DCS' may be different from the first distance DCS of FIG. 14.

Referring again to FIGS. 13 and 14, after moving in the second direction DR2, the stage STG may return to its initial position by moving in a direction opposite to the second direction DR2. That is, the stage STG may move in the direction opposite to the second direction DR2 from the second point P2 to a first point P1. A third camera module CA-3 may measure each of the positions of a (1-3)-th fiducial mark SM1-3 and a (2-3)-th fiducial mark SM2-3 when the center of the stage STG is positioned at the first point P1. A fourth camera module CA-4 may measure each of the positions of a (1-4)-th fiducial mark SM1-4 and a (2-4)-th fiducial mark SM2-4 when the center of the stage STG is positioned at the first point P1.

Thereafter, the amount of thermal expansion of the substrate SUB may be measured again, and the control signal SS for controlling the cooling member COL may be provided in response to the measured amount of thermal expansion of the substrate SUB (S400). The temperature of the cooling member COL and/or the separation distance between the cooling member COL and the substrate SUB in the third direction DR3 may be adjusted by the control signal SS (S500).

That is, while the stage STG reciprocates, the process of measuring the amount of thermal expansion of the substrate SUB and the process of controlling the cooling member COL in response to the measured amount of thermal expansion of the substrate SUB may be performed repeatedly.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. An inkjet printing apparatus comprising:
a head module including a plurality of head nozzles and at least one cooling member, wherein the plurality of head nozzles are arranged in a row along a first direction and configured to discharge a liquid body on a substrate which moves along a second direction crossing the first direction, and the cooling member is spaced apart from the plurality of head nozzles in the second direction and configured to compensate for a temperature of the substrate; and
a control module which provides a control signal for controlling the cooling member to the head module.

2. The inkjet printing apparatus of claim 1, wherein the control signal is a signal for controlling a temperature of the cooling member in response to an amount of thermal expansion of the substrate.

3. The inkjet printing apparatus of claim 1, wherein the control signal is a signal for controlling a separation distance between the cooling member and the substrate in response to an amount of thermal expansion of the substrate.

4. The inkjet printing apparatus of claim 1, further comprising:
a first fiducial mark disposed on the substrate and for measuring an amount of thermal expansion of the substrate.

5. The inkjet printing apparatus of claim 4, wherein the first fiducial mark is positioned at an edge of the substrate.

6. The inkjet printing apparatus of claim 4, further comprising:
a camera module, which measures a position of the first fiducial mark,
wherein the control module provides the control signal based on the measured position of the first fiducial mark.

7. The inkjet printing apparatus of claim 6, further comprising:
a stage on which the substrate is loaded; and
a second fiducial mark disposed on the stage and for measuring an amount of deformation of the camera module.

8. The inkjet printing apparatus of claim 7, wherein the camera module measures the position of the first fiducial mark and a position of the second fiducial mark, and
the control module provides the control signal based on the measured position of the first fiducial mark and the measured position of the second fiducial mark.

9. The inkjet printing apparatus of claim 1, wherein a surface area of the cooling member is equal to a sum of surface areas of the plurality of head nozzles.

10. The inkjet printing apparatus of claim 1, wherein the cooling member includes a cooling water supply pipe through which a cooling water flows.

11. The inkjet printing apparatus of claim 1, wherein the head module moves along the first direction.

12. An inkjet printing method comprising:
discharging a liquid body on a substrate;
measuring an amount of thermal expansion of the substrate; and
compensating a temperature of the substrate in response to a measured amount of thermal expansion of the substrate.

13. The inkjet printing method of claim 12, wherein a heat of the substrate is transferred to a cooling member having a temperature relatively lower than a temperature of the substrate while compensating the temperature of the substrate.

14. The inkjet printing method of claim 13, further comprising:
controlling a temperature of the cooling member after measuring the amount of thermal expansion of the substrate.

15. The inkjet printing method of claim 13, further comprising:
controlling a separation distance between the cooling member and the substrate after measuring the amount of thermal expansion of the substrate.

16. The inkjet printing method of claim 13, wherein the cooling member includes a cooling water supply pipe through which a cooling water flows.

17. The inkjet printing method of claim 12, wherein the amount of thermal expansion of the substrate is measured by measuring a position of a fiducial mark disposed on the substrate while measuring the amount of thermal expansion of the substrate.

18. The inkjet printing method of claim 17, wherein the fiducial mark is positioned at an edge of the substrate.

19. The inkjet printing method of claim 17, wherein the position of the fiducial mark is measured by a camera module.

20. The inkjet printing method of claim 17, wherein the amount of thermal expansion of the substrate is measured by further measuring a position of another fiducial mark disposed on a stage under the substrate and calculating the amount of thermal expansion of the substrate based on both the measured position of a fiducial mark disposed on the substrate and the measured position of the another fiducial mark disposed on the stage.
